(19) United States
(12) Patent Application Publication
(10) Pub. No.: US 2026/0043846 A1
(43) Pub. Date: Feb. 12, 2026

(54) METHOD OF TESTING A DEVICE UNDER TEST AND TEST SYSTEM

(71) Applicant: Rohde & Schwarz GmbH & Co. KG, Muenchen (DE)

(72) Inventor: Niels PETROVIC, Muenchen (DE)

(21) Appl. No.: 18/798,079

(22) Filed: Aug. 8, 2024

(51) Int. Cl. G01R 31/28

(52) U.S. Cl. CPC G01R 31/2879

(57) ABSTRACT

The present disclosure relates to a method of testing a device under test. A device under test is provided that includes a main radio and a low power wake-up receiver. A test and/or measurement instrument for testing the device under test is also provided. A test mode of the device under test is activated in which the main radio is switched off. A plurality of low power wake-up signals is transmitted by the test and/or measurement instrument, wherein the plurality of low power wake-up signals is received by the low power wake-up receiver of the device under test in the test mode. Moreover, a test system is described.

### FIELD OF THE DISCLOSURE

Embodiments of the present disclosure relate to a method of testing a device under test. Further, embodiments of the present disclosure relate to a test system.

### BACKGROUND

In the state of the art, modern communication devices are known that use the telecommunication standard 5G, namely the fifth-generation technology standard for cellular networks.

According to the telecommunication standard, communication devices may comprise a low power wake-up receiver that allows the communication device to save energy by switching off its main radio and only listen on a low power wake-up receiver, abbreviated by LP-WuR.

Once the low power wake-up receiver receives a corresponding low power wake-up signal, abbreviated by LP-WuS, the communication device, particularly its low power wake-up receiver, wakes up the main radio. Once the main radio is woken up, the communication device is in its regular communication mode, enabling the communication device to start a new communication or to continue an already existing communication that was interrupted previously.

However, there is no method known in the state of the art for testing the communication device, particularly its characteristics, as the low power wake-up receiver cannot provide any feedback. The low power wake-up receiver is only enabled to wake up the main radio. Hence, typical testing of the communication device, e.g. throughput testing on a Physical Downlink Shared Channel, PDSCH, is not feasible.

Accordingly, there is a need for a method of testing such a communication device, also called device under test during the testing, as well as a test system which can be used to test characteristics of the device under test with regard to the low power wake-up procedure mentioned above.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a method of testing a device under test. In an embodiment, the method comprises: providing a device under test that comprises a main radio and a low power wake-up receiver; providing a test and/or measurement instrument for testing the device under test; activating a test mode of the device under test in which the main radio is switched off; and transmitting by the test and/or measurement instrument a plurality of low power wake-up signals wherein the plurality of low power wake-up signals is received by the low power wake-up receiver of the device under test in the test mode.

Further, embodiments of the present disclosure provide a method of testing a device under test. In an embodiment, the method comprises: providing a device under test that comprises a main radio and a low power wake-up receiver; providing a test and/or measurement instrument for testing the device under test; activating a test mode of the device under test in which the main radio is switched off; transmitting by the test and/or measurement instrument a low power wake-up signal which is received by the low power wake-up receiver of the device under test in the test mode, causing the device under test to wake up, thereby activating the main radio; and reporting a successful activation to the test and/or measurement instrument via the main radio of the device under test.

In addition, embodiments of the present disclosure provide a test system for testing. In an embodiment, the test system comprises a test and/or measurement instrument as well as a device under test. The device under test comprises a main radio and a low power wake-up receiver. The device under test has a test mode in which the main radio is switched off. The test and/or measurement instrument is capable of transmitting low power wake-up signals to the device under test that receives the low power wake-up signals. The test system is capable of counting the number of successful activations of the device under test by the low power wake-up signals and/or the number of low power wake-up signals received by the device under test.

Accordingly, the present disclosure provides a method as well as a test system which are enabled for testing the characteristics of the device under test with regard to the low power wake-up procedure.

According to a first example, the device under test remains in its test mode even though the plurality of low power wake-up signals is received by the device under test. In this example, the test mode is thus resilient against the low power wake-up signal since reception of a low power wake-up signal does not immediately cause device under test to wake up and to exit the test mode. Consequently, it is possible that the device under test receives more than one low power wake-up signal during the test mode in a continuous manner, namely without exiting or interrupting the test mode. In this example, the test system, for example the device under test itself, is capable of counting the number of low power wake-up signals received, wherein this information is used for determining the characteristics of the device under test with regard to the low power wake-up procedure.

According to a second example, the low power wake-up signal causes the device under test to wake up, thereby activating the main radio. This means that the test mode is exited. The device under test immediately reports the successful activation to the test and/or measurement instrument via the main radio of the device under test, which has been activated due to the reception of the low power wake-up signal which was internally processed by the device under test. Accordingly, the test and/or measurement instrument is informed about the successful activation due to the direct reporting performed by the device under test. In this example, the test system, for example the test and/or measurement instrument, is capable of counting the number of successful activations of the device under test by the low power wake-up signals by counting the number of reports received from the device under test.

Generally, the second example differs from the first example with regard to the resiliency of the test mode. In the second example, the device under test directly wakes up once a low power wake-up signal was received successfully, which is reported to the test and/or measurement instrument. In contrast thereto, the test mode according to the first example is more resilient since the device under test does not directly wake up once a low power wake-up signal was received successfully, thereby enabling the device under test to receive the plurality of low power wake-up signals during the test mode in a continuous manner.

In other words, the alternatives/examples distinguish from each other in that the device under test according to the fist alternative remains in the test mode even though a low power wake-up signal was received successfully. whereas the device under test according to the second alternative immediately exits the test mode in case a low power wake-up signal was received successfully.

Embodiments of the test system is generally enabled to perform both methods for testing the characteristics of the device under test with regard to the low power wake-up procedure, which were described above.

According to an aspect, the low power wake-up receiver, for example, is not capable of transmitting a signal to the test and/or measurement instrument. In an embodiment, the low power wake-up receiver is only enabled to receive a low power wake-up signal and to process the low power wake-up signal. However, information cannot be transmitted by the low power wake-up receiver to a separately formed device, e.g. the test and/or measurement instrument.

Generally, the low power wake-up receiver is only enabled to wake up the main radio of the device under test directly or indirectly such that the main radio of the device under test is needed for initiating or resuming a communication.

A further aspect provides that the device under test, for example, remains in its test mode until the device under test wakes up. In other words, the test mode is exited in case the main radio is activated or the test mode is exited by activation of the main radio which is equivalent to the device under test waking up. Of course, the device under test may get back into the test mode afterwards, but activating the main radio relates to at least interrupting the test mode.

As indicated above, the device under test stays in the test mode according to the first alternative even though at least one low power wake-up signal was successfully received. In this alternative, the test mode is configured such that the device under test does not wake up directly, but remains in its sleep mode. For instance, the test mode is configured in this alternative such that the low power wake-up receiver does not directly forward a control signal for activating the main radio.

Further, the test mode may be configured such that the low power wake-up receiver of the device under test does not wake up the main radio by each low power wake-up signal received, but only of a predefined number of low power wake-up signals received. Accordingly, it is ensured that the test mode endures a certain number of successfully received low power wake-up signals. Only after receiving the predefined number, the low power wake-up receiver controls the main radio to wake up. As already indicated above, the low power wake-up receiver may directly control the main radio or indirectly control the main radio to wake up.

In an embodiment, the device under test may count the number of low power wake-up signals received. Hence, the successful receptions are counted by the device under test without directly reporting the successful reception to the test and/or measurement instrument. Hence, the device under test may internally store the information about the number of low power wake-up signals received successfully so as to be enabled to report the number once the device under test wakes up.

In an embodiment, the low power wake-up receiver itself may be enabled to count the number of successful receptions. Alternatively, the low power wake-up receiver may forward a signal to a counter circuit in case a low power wake-up signal was received successfully, wherein the counter circuit counts the number of successful receptions. Once the predefined number of low power wake-up signals has been reached, the counter circuit may issue a control signal for waking up the main radio.

For instance, the device under test automatically exits the test mode after receiving a predefined number of low power wake-up signals. Once the predefined number of low power wake-up signals has been received, they cause the device under test to automatically exit the test mode. Actually, the predefined number of low power wake-up signals may cause the device under test to wake up the main radio, which corresponds to exiting the test mode.

Alternatively, the device under test may automatically exit the test mode after a predefined period of time. Thus, the test mode is at least interrupted or stopped after the predefined period of time ended. The duration associated with the period of time may be deemed to be sufficient for performing the tests on the device under test. Generally, the predefined period of time may be assigned to a certain number of low power wake-up signals transmitted by the test and/or measurement instrument. In other words, the test and/or measurement instrument may be controlled to transmit a predefined number of low power wake-up signals in the predefined period of time or rather to transmit the low power wake-up signals in a cyclic manner, wherein a temporal gap between two successive low power wake-up signals is defined. Hence, the predefined period of time is indicative of a predefined number of low power wake-up signals transmitted.

In an embodiment, the device under test may be manually prompted to exit the test mode. A user of the test system may issue a command that is received and processed by the device under test to exit the test mode.

In an embodiment, the main radio may be activated when the device under test exits the test mode such that the device under test is enabled to transmit information to the test and/or measurement instrument. Since the low power wake-up receiver is not enabled to transmit any information to the test and/or measurement instrument, the device under test has to use the main radio for transmitting the respective information. The information transmitted to the test and/or measurement instrument via the main radio may comprise information concerning the test procedure performed, e.g. the number of successful receptions of low power wake-up signals.

Accordingly, the device under test may, for example, report the number of low power wake-up signals received successfully to the test and/or measurement instrument after exiting the test mode such that the test and/or measurement instrument is enabled to further process the information for analyzing/evaluating the characteristics of the device under test. As mentioned above, the main radio is activated once the device under test has exited the test mode such that the reporting can be performed via the main radio.

Another aspect provides that the test and/or measurement instrument, for example, receives a report from the device under test. In an embodiment, the report comprises information about the number of low power wake-up signals received successfully. In an embodiment, the test and/or measurement instrument compares the reported number of low power wake-up signals received with a number of low power wake-up signals transmitted by the test and/or measurement instrument. Since the test and/or measurement instrument transmits the low power wake-up signals, the test and/or measurement instrument is aware of the number of low power wake-up signals transmitted. The test and/or measurement instrument can compare this number to the number of successful receptions reported by the device under test after exiting the test mode so as to evaluate the characteristics of the device under test. In an embodiment, the test and/or measurement instrument may determine a rate of successful receptions/activations based on the report received and the information internally gathered, namely the number of transmitted low power wake-up signals.

Alternatively or additionally, the test and/or measurement instrument may compare the reported number of low power wake-up signals received with a threshold value. For instance, the test procedure may comprise a certain number of low power wake-up signals to be transmitted by the test and/or measurement instrument so that a threshold value may be defined previously. The threshold value shall be reached so as to ensure that the device under meets a certain criteria such that the device under test passes the test.

Concerning the second alternative described above, the steps of transmitting the low power wake-up signal to the device under test and reporting the successful activation are repeated several times. Thus, the test procedure relates to a cycle of entering and exiting the test mode by the device under test. In the test mode, the device under test is enabled to receive the low power wake-up signal transmitted by the test and/or measurement instrument, causing the device under test to exit the test mode and to report the successful activation via the main radio. After reporting the successful activation, the device under test goes back into the test mode for being enabled to receive the low power wake-up signal transmitted by the test and/or measurement instrument again. Therefore, the respective steps mentioned above are repeated several times during the test procedure.

In an embodiment, the test and/or measurement instrument receives the reports from the device under test, wherein the test and/or measurement instrument is enabled to count the number of reports received by the device under test, which is indicative of the successful activations. Accordingly, the test and/or measurement instrument continuously gathers the information with regard to the successful activations/receptions of the device under test.

In an embodiment, the test and/or measurement instrument compares the number of reports received with the number of low power wake-up signals transmitted by the test and/or measurement instrument as indicated above. The test and/or measurement instrument is aware of the number of low power wake-up signals transmitted, thereby enabling the test and/or measurement instrument to compare the number of reports received with the number of low power wake-up signals transmitted in order to identify a rate of successful activations of the device under test.

Alternatively or additionally, the test and/or measurement instrument may compare the number of reports received with a threshold value. Again, the test procedure may comprise a predefined number of low power wake-up signals to be transmitted by the test and/or measurement instrument, wherein the threshold value may be defined that is necessary for passing the test. In case the number of reports received does not exceed the threshold value, the device under test has not passed the test accordingly.

In general, the test system is enabled to perform both alternative methods for testing the device under test, which were described above.

Accordingly, the low power wake-up receiver of the device under test may be capable of receiving a plurality of low power wake-up signals in the test mode, wherein the device under test is capable of staying in the test mode while receiving the plurality of low power wake-up signals, but counting the number of low power wake-up signals received. The device under test may stay in the test mode for a certain amount of time even though several low power wake-up signals are received successfully. The test mode is configured such that the device under test does not directly wake up when receiving a low power wake-up signal. In an embodiment, the device under test, in its test mode, may count the number of low power wake-up signals received successfully during that time while reporting the number counted afterwards via the main radio once the device under test has exited the test mode, e.g. the main radio has been activated. The respective report including the number of low power wake-up signals received during the test mode is forwarded to the test and/or measurement instrument for further analysis.

Alternatively, the low power wake-up receiver of the device under test is capable of waking up by the low power wake-up signals received, thereby activating the main radio. The device under test is capable of reporting a successful activation to the test and/or measurement instrument via the main radio of the device under test. As indicated above, the second alternative relates to immediately reporting each successful activation so that the device under test idles between the test mode and the activated mode, also called communication mode or normal operation mode. The test and/or measurement instrument, receiving the reports from the device under test, counts the number of reports received while comparing the number of reports received with a threshold value and/or the number of low power wake-up signals transmitted in order to determine whether the device under test has passed the test or not. The test and/or measurement instrument processes the information further for analysis.

Generally, the test and/or measurement instrument may determine a rate based on the information received from the device under test, e.g. the counted number of successful activations reported once or rather the several reports for each successful activation. The respective rate may relate to a missed detection rate, MDR, or a false alarm rate, FAR. Generally, a key performance indicator, KPI, may be determined by the test and/or measurement instrument based on the information gathered, thereby enabling comparison of different devices under test among each other.

In an embodiment, the test and/or measurement instrument can determine whether the device under test has passed or failed the test.

In an embodiment, the device under test may relate to a user equipment, UE. For instance, the device under test is a mobile phone or a customer premises equipment, CPE.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows an overview of a test system according to an embodiment of the present disclosure, and

FIG. 2 schematically shows a flow chart illustrating two embodiments of the method of testing a device under test according to the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

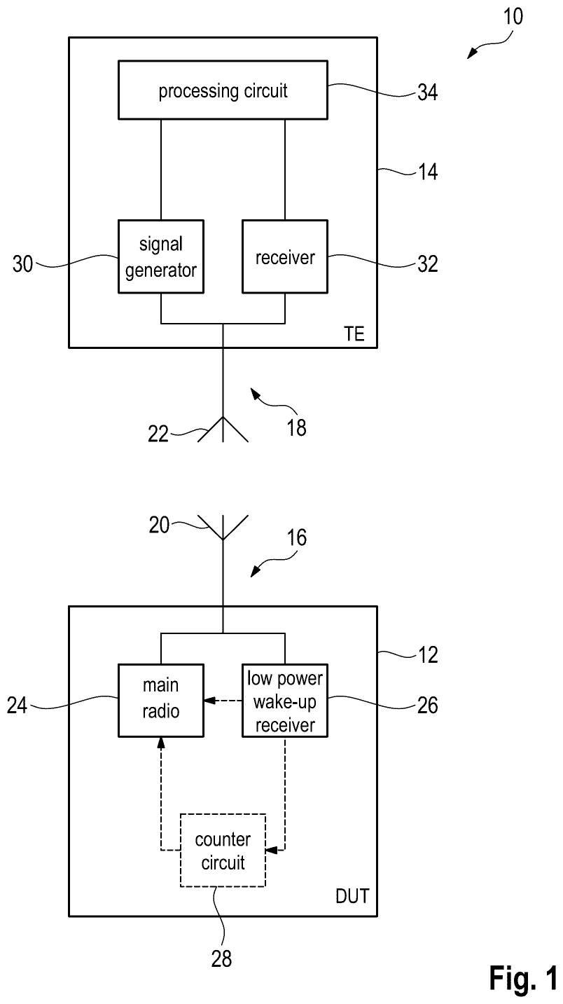

In FIG. 1, a test system 10 is shown that is used for testing a device under test 12 (DUT). The test system 10 comprises the device under test 12 as well as a test and/or measurement instrument 14, also called test equipment (TE). The test and/or measurement instrument 14 is capable of communicating with the device under test 12 over-the-air OTA. Accordingly, the device under test 12 as well as the test and/or measurement instrument 14 may each comprise a radio frequency, RF, front end 16, 18 having at least an antenna 20, 22. Generally, two or more antennas may be provided.

The device under test 12 comprises a main radio 24 as well as a low power wake-up receiver 26. The low power wake-up receiver 26 is only capable of receiving a low power wake-up signal. In other words, the low power wake-up receiver 26 is not capable of transmitting a signal to the test and/or measurement instrument 14. For forwarding information/signals to the test and/or measurement instrument 14, the device under test 12 has to use the main radio 24.

However, both the main radio 24 and the low power wake-up receiver 26 are connected with the antenna 20 such that the low power wake-up receiver 26 may receive the low power wake-up signal received over the antenna 20.

In an embodiment, the device under test 12 may also comprises an optional counter circuit 28 that is interconnected between the low power wake-up receiver 26 and the main radio 24 as indicated in FIG. 1.

The test and/or measurement instrument 14 comprises a signal generator 30 comprising circuitry that is capable of generating at least a low power wake-up signal to be forwarded to the device under test 12 via the antenna 22. In addition, the test and/or measurement instrument 14 comprises a receiver 32 that is connected with the antenna 22 for receiving a signal transmitted by the device under test 12, for example the main radio 24 of the device under test 12.

The test and/or measurement instrument 14 also includes a processing circuit 34 that is connected with the signal generator 30 and the receiver 32. The processing circuit 34 may be capable of controlling the signal generator 30 and/or analyzing signals received by the receiver 32.

The over-the-air, OTA, connection established between the device under test 12 and the test and/or measurement instrument 14 may relate to a 5G communication (e.g., implemented under the 5G standard). As indicated above, the communication however takes place between the main radio 24 of the device under test 12 and the receiver 32. In addition, the test and/or measurement instrument 14 is enabled to generated and transmit low power wake-up signals by the signal generator 30, which are received by the low power wake-up receiver 26 that however cannot respond thereto.

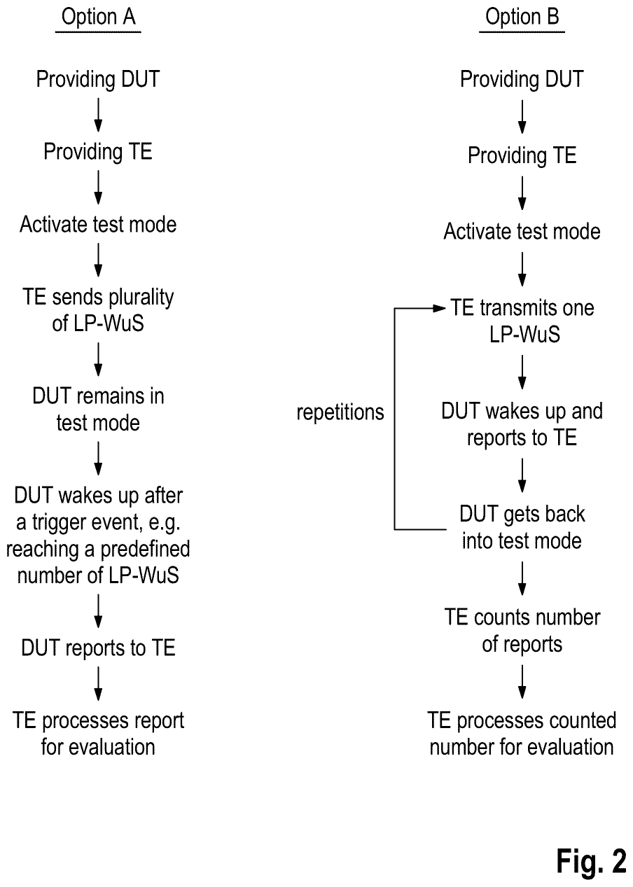

The test system 10 shown in FIG. 1 is generally enabled to perform a method of testing the device under test 12, examples of which are shown in FIG. 2 to which reference is made hereinafter. In FIG. 2, two different methods for testing the device under test 12 are illustrated, namely a first alternative, also called option A) as well as a second alternative, also called option B).

According to both alternatives, the device under test 12 is provided that comprises the main radio 24 and the low power wake-up receiver 26. The test and/or measurement instrument 14 is also provided that is used for testing the device under test 12.

A test mode of the device under test 12 may be activated, for instance by the test and/or measurement instrument 14. Accordingly, the test and/or measurement instrument 14 may configure the device under test 12 to use the test mode, also called low power wake-up receiver test mode, LP-WuR test mode. The configuration may be done via a 3GPP signaling.

In an embodiment, this step may relate to an attach procedure between the device under test 12 and the test and/or measurement instrument 14.

According to the first alternative, the test and/or measurement instrument 14 transmits a plurality of low power wake-up signals, LP-WuS to the device under test 12, wherein the plurality of low power wake-up signals is received by the low power wake-up receiver 26 of the device under test 12 in the test mode.

The test and/or measurement instrument 14 may transmit the low power wake-up signals to the device under test 12 for a specified time or for a specified number. In other words, the number of low power wake-up signals to be transmitted is predefined.

In the test mode, the device under test 12 may count the number of low power wake-up signals received, namely the number of events. Moreover, the device under test 12 may also calculate a key performance indicator, KPI, for instance missed detection rate, MDR, or a false alarm rate, FAR. For doing so, the device under test 12 may receive further information, e.g. the number of low power wake-up signals to be transmitted, which may be predefined as indicated above.

The device under test 12 remains in the test mode until the device under test 12 wakes up. Hence, the test mode may be configured such that the low power wake-up receiver 26 of the device under test 12 does not wake up the main radio 24 by each low power wake-up signal received, but only after a certain trigger event being reached, for instance after a predefined number of low power wake-up signals was received by the device under test 12.

Accordingly, the device under test 12 counts the number of low power wake-up signals received in the test mode so as to determine the respective number. This can be done by the low power wake-up receiver 26 or by the counter circuit 28. In case of using the counter circuit 28, the low power wake-up receiver 26 forwards a signal to the counter circuit 28 for each received low power wake-up signal, thereby enabling the counter circuit 28 to count the number of successful received low power wake-up signals. Once the counter circuit 28 has identified that the number of successfully receptions reaches or exceeds the predefined number of low power wake-up signals, the counter circuit 28 may wake up the main radio 24, thereby exiting the test mode automatically.

In case the device under test does not comprise a counter circuit 28, the low power wake-up receiver 26 may count the number of successful receptions by itself.

Alternatively to the predefined number of low power wake-up signals successfully received, the device under test 12 may automatically exit the test mode after a predefined period of time. Thus, the predefined period of time may relate to the trigger event. This may be done in case the number of low power wake-up signals transmitted by the test and/or measurement instrument 14 is associated with a specified time, as indicated above.

In an embodiment, the device under test 12 may also be manually prompted to exit the test mode. Accordingly, the trigger event may be a command issued to the device under test 12.

Once the device under test 12 exited the test mode, the device under test 12 transmits information to the test and/or measurement instrument 14, e.g. reports to the test and/or measurement instrument 14.

For instance, the number of low power wake-up signals successfully received is reported to the test and/or measurement instrument 14. The respective report is transmitted via the main radio 24 to the device under test 12, which has been activated when exiting the test mode.

The test and/or measurement instrument 14 receives the report from the device under test 12, which comprises information about the number of low power wake-up signals successfully received or the KPI. The test and/or measurement instrument 14 processes the report for evaluation.

For instance, the test and/or measurement instrument 14 compares the reported number with the number of low power wake-up signals transmitted by the test and/or measurement instrument 14, as the test and/or measurement instrument 14 is aware of the number of transmissions. Alternatively or additionally, the reported number may be compared to a threshold value in case the test and/or measurement instrument 14 was configured to transmit a predefined number of low power wake-up signals.

In any case, a rate of successful receptions/activations of the device under test 12 can be determined by the processing circuit 34 of test and/or measurement instrument 14 after comparing the reported number with the number of transmissions or with the threshold value. Hence, the characteristics of the device under test 12 with regard to the low power wake-up procedure can be evaluated. In an embodiment, the test and/or measurement instrument 14 may indicate whether the device under test 12 has passed or failed the test.

According to the second alternative, the test and/or measurement instrument 14 transmits one low power wake-up signal that is received by the low power wake-up receiver 26 of the device under test 12 in the test mode, causing the device under test 12 to directly wake up, thereby activating the main radio 24.

Then, the device under test 12 directly reports the successful activation to the test and/or measurement instrument 14 via the main radio 24 of the device under test 12. After reporting, the device under test 12 gets back into the test mode for being enabled to receive the next low power wake-up signal transmitted by the test and/or measurement instrument 14.

The respective steps of transmitting the low power wake-up signal via the test and/or measurement instrument 14 to the device under test 12 as well as the reporting of the successful activations/receptions are repeated several times so that the test and/or measurement instrument 14 is enabled to count the number of reports received from the device under test 12.

After a certain period of time or rather at the end of a test procedure, the test and/or measurement instrument 14 is enabled to compare the number of reports received from the device under test 12 with the number of low power wake-up signals transmitted and/or the threshold value, as described with respect to the first alternative.

Again, the test and/or measurement instrument 14 is enabled to evaluate the characteristics of the device under test 12 with regard to the low power wake-up procedure, thereby evaluating whether the device under test 12 has passed or failed the tests performed.

For the second alternative, the main radio connection needs to be configured to minimize errors on the main radio, e.g. high signal-to-noise radio, SNR, on Physical Downlink Control Channel, PDCCH.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,”etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components, such as the device under test 12 (DUT), the test and/or measurement instrument 14, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B. ”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method of testing a device under test, wherein the method comprises the steps of:
providing a device under test that comprises a main radio and a low power wake-up receiver,
providing a test and/or measurement instrument for testing the device under test,
activating a test mode of the device under test in which the main radio is switched off, and
transmitting by the test and/or measurement instrument a plurality of low power wake-up signals, wherein the plurality of low power wake-up signals is received by the low power wake-up receiver of the device under test in the test mode.

2. The method according to claim 1, wherein the low power wake-up receiver is not capable of transmitting a signal to the test and/or measurement instrument.

3. The method according to claim 1, wherein the device under test remains in its test mode until the device under test wakes up.

4. The method according to claim 1, wherein the test mode is configured such that the low power wake-up receiver of the device under test does not wake up the main radio by each low power wake-up signal received, but only after a predefined number of low power wake-up signals received.

5. The method according to claim 1, wherein the device under test counts the number of low power wake-up signals received.

6. The method according to claim 1, wherein the device under test automatically exits the test mode after receiving a predefined number of low power wake-up signals.

7. The method according to claim 1, wherein the device under test automatically exits the test mode after a predefined period of time.

8. The method according to claim 1, wherein the device under test is manually prompted to exit the test mode.

9. The method according to claim 1, wherein the main radio is activated when the device under test exits the test mode such that the device under test is enabled to transmit information to the test and/or measurement instrument.

10. The method according to claim 1, wherein the device under test reports the number of low power wake-up signals received to the test and/or measurement instrument after exiting the test mode.

11. The method according to claim 1, wherein the test and/or measurement instrument receives a report from the device under test, the report comprising information about the number of low power wake-up signals received, and wherein the test and/or measurement instrument compares the reported number of low power wake-up signals received with a number of low power wake-up signals transmitted by the test and/or measurement instrument.

12. The method according to claim 1, wherein the test and/or measurement instrument receives a report from the device under test, the report comprising information about the number of low power wake-up signals received, and wherein the test and/or measurement instrument compares the reported number of low power wake-up signals received with a threshold value.

13. A method of testing a device under test, wherein the method comprises the steps of:
providing a device under test that comprises a main radio and a low power wake-up receiver,
providing a test and/or measurement instrument for testing the device under test,
activating a test mode of the device under test in which the main radio is switched off,
transmitting by the test and/or measurement instrument a low power wake-up signal which is received by the low power wake-up receiver of the device under test in the test mode, causing the device under test to wake up, thereby activating the main radio, and
reporting a successful activation to the test and/or measurement instrument via the main radio of the device under test.

14. The method according to claim 13, wherein the steps of transmitting the low power wake-up signal to the device under test and reporting the successful activation are repeated several times.

15. The method according to claim 13, wherein the test and/or measurement instrument counts the number of reports received by the device under test.

16. The method according to claim 13, wherein the test and/or measurement instrument compares the number of reports received with a number of low power wake-up signals transmitted by the test and/or measurement instrument.

17. The method according to claim 13, wherein the test and/or measurement instrument compares the number of reports received with a threshold value.

18. A test system for testing, wherein the test system comprises a test and/or measurement instrument as well as a device under test, wherein the device under test comprises a main radio and a low power wake-up receiver, wherein the device under test has a test mode in which the main radio is switched off, wherein the test and/or measurement instrument is capable of transmitting low power wake-up signals to the device under test that receives the low power wake-up signals, and wherein the test system is capable of counting the number of successful activations of the device under test by the low power wake-up signals and/or the number of low power wake-up signals received by the device under test.

19. The test system according to claim 18, wherein the low power wake-up receiver of the device under test is capable of receiving a plurality of low power wake-up signals in the test mode, and wherein the device under test is capable of staying in the test mode while receiving the plurality of low power wake-up signals, but counting the number of low power wake-up signals received.

20. The test system according to claim 18, wherein the low power wake-up receiver of the device under test is capable of waking up by the low power wake-up signals received, thereby activating the main radio, and wherein the device under test is capable of reporting a successful activation to the test and/or measurement instrument via the main radio of the device under test.
